(19) United States
(12) Patent Application Publication
(10) Pub. No.: US 2001/0026572 A1
(43) Pub. Date: Oct. 4, 2001

(54) Method and apparatus for measuring a semiconductor laser device

(76) Inventors: Junichi Shimizu, Tokyo (JP); Kouichi Komatsu, Tokyo (JP)

Correspondence Address: McGinn & Gibb, PLLC, 8321 Old Courthouse Road, Suite 200, Vienna, VA, 22182-3817, US

(21) Appl. No.: 09/820,612

(22) Filed: Mar. 30, 2001

(30) Foreign Application Priority Data
Mar. 31, 2000 (JP) 2000-96598

(51) Int. Cl. H01S 5/00

(52) U.S. Cl. 372/45

(57) ABSTRACT

An apparatus for evaluating a long-term stability of the lasing wavelength of a semiconductor laser includes a constant temperature bath for receiving therein a semiconductor laser device, a wavelength measuring member for measuring the absolute wavelength of the semiconductor laser device, a temperature sensor disposed in the vicinity of the semiconductor laser device for measuring the test temperature of the semiconductor laser device, and a correction member for correcting the measured absolute wavelength based on the test temperature.

### BACKGROUND OF THE INVENTION

(a) Field of the Invention

The present invention relates to method and apparatus for measuring a semiconductor laser device. In particular, the present invention relates to method and apparatus for evaluating the long-term wavelength stability (or reliability) of a semiconductor laser device with a higher accuracy.

(b) Description of the Related Art

In recent years, to semiconductor laser devices widely used in optical communication systems in particular, optical communication technologies using wavelength division multiplexing (WDM) schemes are becoming key technologies for increasing the amount of information to be transmitted. Among the long-term reliabilities required of the devices used in WDM optical communication systems is the reliability of the lasing wavelength as well as the reliability of the lifetime of the semiconductor laser device.

More specifically, WDM optical communication systems have a configuration wherein the wavelengths are separated at a pitch of e.g. 50 GHz. Therefore, aging changes in the lasing wavelength of the semiconductor lasers cause adjacent wavelengths in the systems to overlap each other, thereby generating obstacles on the networks. To avoid such obstacles, the laser devices to be used in VVDM optical communication systems require a long-term wavelength reliability of, e.g., Δλ≦±0.1 nm in wavelength variation for 2×10⁵ hours (approximately 25 years). As a precondition for secured long-term wavelength reliability, the accuracy of the wavelength measured is of importance.

Nevertheless, a semiconductor laser device varies in the lasing wavelength thereof depending on the driving current (or injected current) and temperature used therein. The control to maintain the driving current supplied to the semiconductor laser device at a constant with a high degree of accuracy is feasible to achieve. On the other hand, the accuracy of the test temperature is determined by the temperature controlling precision of the constant temperature bath. In the case of using a commercially-available, inexpensive constant temperature bath such as used in conventional degradation-accelerating tests (or accelerated degradation tests) at fixed temperatures, the temperature controlling precision typically falls on the order of ±0.2° C., which precludes temperature control with high precision. On this account, the high-precision temperature control requires a special-structured, expensive constant temperature bath. This inevitably raises the costs of the test apparatus itself that determines as to whether or not the semiconductor laser device satisfies the long-term wavelength reliability.

### SUMMARY OF THE INVENTION

In view of the foregoing, an object of the present invention is to provide apparatus and method for measuring the long-term stability of a semiconductor laser device, which are capable of monitoring the lasing wavelength of a semiconductor laser device for a long term substantially without the wavelength variation due to changes in the test temperature, while using a commercially-available inexpensive constant temperature bath, thereby allowing high-accuracy evaluations of the long-term wavelength reliability of the semiconductor laser device.

The present invention provides an apparatus for evaluating a wavelength stability of a semiconductor laser device including a container for receiving therein a semiconductor laser device under test, a wavelength measurement member for measuring an absolute wavelength of the semiconductor laser device, a temperature measurement member for measuring a test temperature of the semiconductor laser device, and a correction member for correcting the absolute wavelength measured by the wavelength measurement member based on the test temperature.

The present invention also provides a method for evaluating a wavelength stability of a semiconductor laser device including the steps of driving a semiconductor laser device under test received in a constant temperature bath, measuring an absolute wavelength of the driven semiconductor laser device, measuring a test temperature of the semiconductor laser device by using a temperature sensor disposed in a vicinity of the semiconductor laser device, and correcting the absolute wavelength measured by the wavelength measurement member based on the test temperature.

In accordance with the apparatus and the method of the present invention, since the absolute temperature of the wavelength of the semiconductor laser device under test is corrected by the test temperature actually measured by the temperature sensor or temperature measurement member disposed in the vicinity of the semiconductor laser device in the container, the accuracy of the measurement using a commercially-available bath is improved so that an accurate evaluation of the long-term stability for the semiconductor laser device can be obtained.

### BRIEF DESCRIPTION OF THE DRAWINGS

FIG. 1 is a diagram schematically showing a measuring apparatus for evaluating the long-term wavelength reliability of a semiconductor laser device according to an embodiment of the present invention;

FIG. 2 is a graph showing an example of the results of the wavelength reliability evaluations for situations where a commercially-available constant temperature bath is used without the application of the test temperature correcting processing; and

FIG. 3 is a graph showing the results of the wavelength reliability evaluations in which the thermistor resistances are used to correct the absolute wavelengths.

### DETAILED DESCRIPTION OF THE PREFERRED EMBODIMENT

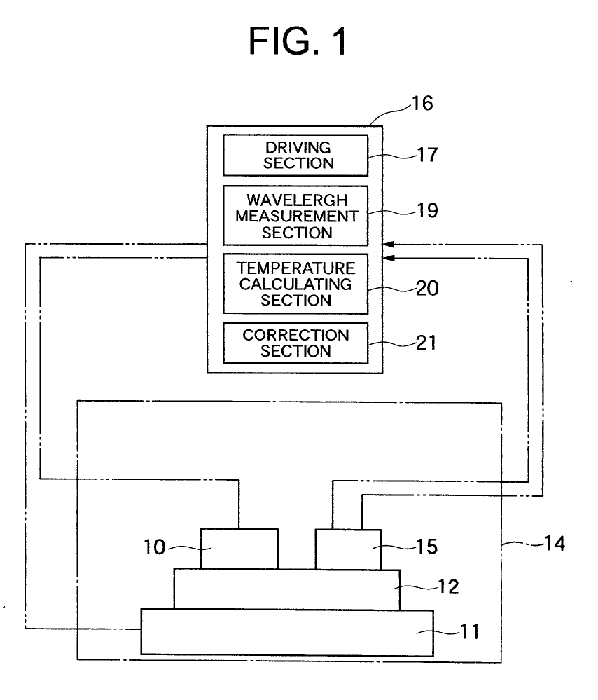

Now, referring to the drawings, the present invention will be described in further details in conjunction with the embodiment of the present invention. FIG. 1 is a diagram schematically showing a measuring apparatus for evaluating the long-term wavelength reliability of a semiconductor laser device according to an embodiment of the present invention. A semiconductor laser device to be measured by this measuring apparatus is mounted on a sub-mount 11 via a heat sink 12.

The measuring apparatus of the present embodiment includes a constant temperature bath (or container) 14, a thermistor chip (temperature sensor) 15, and a computer system 16. The constant temperature bath 14 receives therein, under predetermined conditions, the sub-mount 11 mounting thereon having the semiconductor laser device 10. The thermistor chip 15 is arranged in the vicinity of the semiconductor laser device 10 on the heat sink 12 of the sub-mount 11 in the constant temperature bath 14. The constant temperature bath 14 uses one of commercially-available inexpensive type.

As the thermistor chip 15 for temperature monitoring, one having a resistance of 10 k at a room temperature (for example, 25° C.) and a temperature coefficient of 300/° C. is used. Measuring instruments such as a commercially-available multimeter are capable of measurements with precision of the order of several tens of ohms. This means that the thermistor chip 15 is capable of temperature monitoring with a precision of approximately 0.03° C./Ω. Accordingly, the resistance of this thermistor 15 can be used to correct the measured wavelength to offer a wavelength measuring accuracy of ±0.003 nm, in distributed feedback (DFB) lasers.

The computer system 16 includes a driving section 17, wavelength measuring section 19, temperature calculating section 20, and correction section 21. The driving section 17 supplies a predetermined driving current to drive the semiconductor laser device 10. The wavelength measuring section 19 measures the semiconductor laser device 10 in the heated constant temperature bath 14 for the absolute wavelength thereof. The temperature calculating section 20 calculates the test temperature of the measured semiconductor laser device 10 based on the resistance of the thermistor chip 15. The correction section 21 performs such a correction that the absolute wavelength measured by the wavelength measuring section 19 is compensated by the variation corresponding to a change in the test temperature, based on a calculated temperature value obtained by the temperature calculating section 20, to thereby obtain a corrected absolute wavelength.

The temperature calculating section 20 performs temperature monitoring in accordance with the resistance change of the thermistor 15, with precision to 0.03° C./Ω.

The correction section 21 estimates in advance the correction temperature coefficients effected to the lasing wavelengths of individual semiconductor laser device. In DFB lasers, the coefficient is usually around 0.09 nm/° C. This correction temperature coefficient is used to correct the absolute wavelength obtained by the wavelength measuring section 19 in accordance with the calculated temperature, which is obtained by the temperature calculating section 20 based on the signal from the thermistor 15. This correction may be made in real time in association with the measurement of the absolute wavelength, or may be performed collectively after a series of absolute wavelengths and test temperatures are obtained.

Next, description will be given of the measuring method using the measuring apparatus of the present embodiment. For a start, in the constant temperature bath 14, the sub-mount 11 mounting thereon the semiconductor laser device 10 to be tested is set in a predetermined condition, followed by installation of predetermined wiring in connection with the semiconductor laser device 10. Moreover, the thermistor 15 is placed at a predetermined position on the heat sink 12, thereby creating the condition for measuring the long-term stability of the semiconductor laser device 10.

Then, at a temperature of 100° C., a desired driving current is injected from the driving section 17 into the semiconductor laser device 10. This makes the semiconductor laser device 10 lase in an automated power control (APC) or automated current control (ACC) mode, thereby starting the high-temperature, degradation-accelerating test. The computer system 16 also obtains measurements including a driving voltage V_{f} and a threshold current Iₜₕ for lasing the semiconductor laser device 10.

Under the lasing condition described above, the wavelength measuring section 19 samples the absolute wavelength of the semiconductor laser device 10 at each predetermined time instant. In the meantime, the temperature calculating section 20 calculates a temperature variation from the variations of the resistance of the thermistor 15, thereby obtaining the present test temperature as the calculated temperature value.

Moreover, the correction section 21 converts the absolute wavelength of each sampling time measured by the wavelength measuring section 19 into an absolute wavelength compensated by the variation corresponding to the variation of the test temperature, based on the calculated temperature value and the correction temperature coefficient 0.09 nm/° C. The computer system 16 keeps monitoring the absolute wavelength for a predetermined time interval (for example, 2000 hours). Based on the information obtained thus, the semiconductor laser device 10 is evaluated for the long-term wavelength reliability thereof.

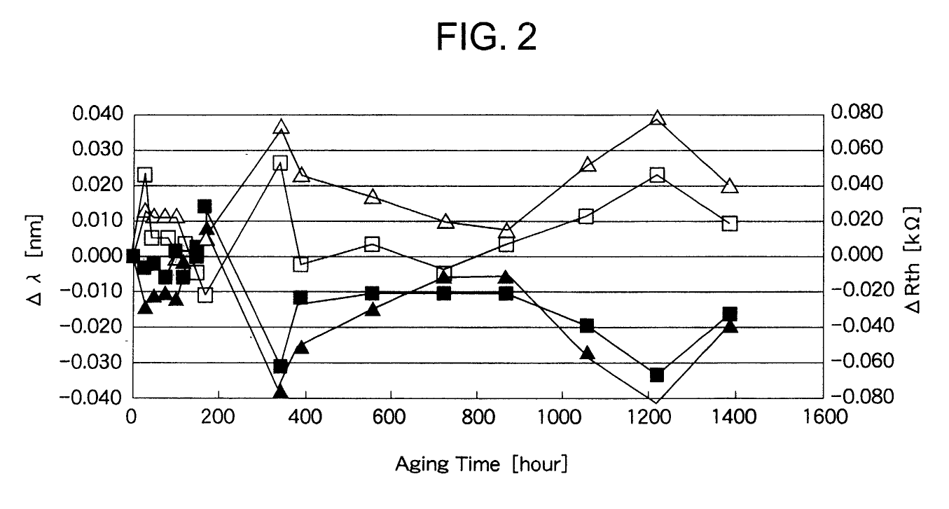

FIG. 2 shows an example of the results of the wavelength measurements conducted in a commercially-available constant temperature bath without execution of the correction processing according to the present embodiment. In this example, two DFB lasers are used as samples to be measured. The samples under the measurements are energized at each appropriate time instant, and measured for absolute wavelength and thermistor resistance. In the graph, Δ indicates the variations of the absolute wavelength of the sample 1, ▴ the variations of the thermistor resistance of the sample 1, □ the variations of the absolute wavelength of the sample 2, and ▪ the variations of the thermistor resistance of the sample 2.

In the test described above, no energization is conducted other than during the absolute wavelength measurements. Thus, a high-temperature, accelerated-degradation is not likely to occur, with little generation of wavelength deterioration. Nevertheless, it can be seen that the measured absolute wavelength λ varied within the range of

Δλ=±0.02 nm

in the described time. Here, since the lasing wavelength varies in approximately 0.1 nm/° C., the variation of

Δλ=±0.02 nm

is equivalent to

ΔT=±0.2° C. (T is the test temperature).

This means that the constant temperature bath in use was controlled within the range of ±0.2° C. in the test temperature.

Moreover, the thermistor resistances measured at the same time corroborate that the measured wavelengths become shorter with falling temperatures (increasing thermistor resistances), and that the measured wavelength become longer with rising temperatures. As seen from above, when temperature control is simply conducted in a commercially-available constant temperature bath without the correcting processing of the present invention before the measurement of the long-term wavelength reliability, the wavelength measurement cannot be made with sufficient accuracy.

To measure the semiconductor laser device 10 for the lasing wavelength thereof with a higher accuracy, the device under test is generally subjected to strict temperature control. In the case of the measurement using a commercially-available constant temperature bath, the control temperature of the constant temperature bath is usually around ±0.2° C. Accordingly, provided that the device under test in the constant temperature bath is a DFB laser, the measured wavelength accuracy is on the order of ±0.02 nm since the temperature coefficient of the lasing wavelength typically falls around 0.1 nm/° C.

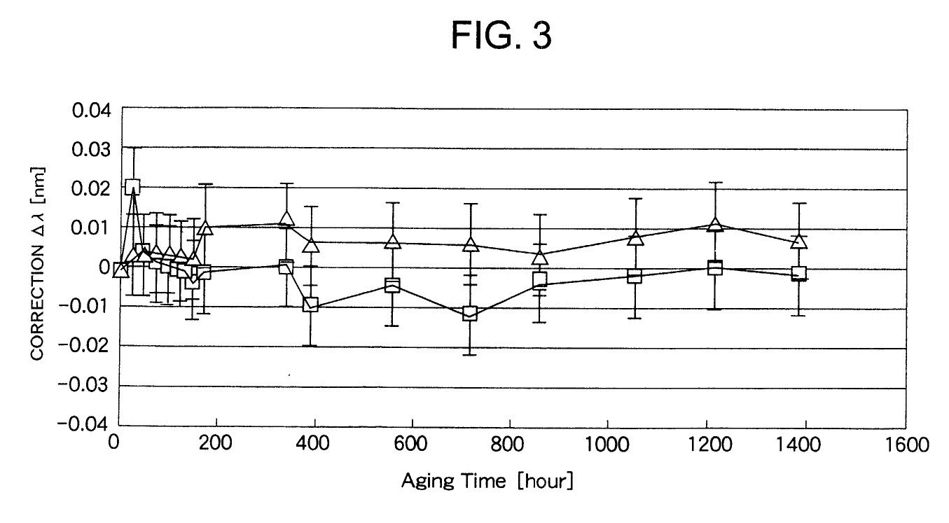

FIG. 3 is a graph showing an example of the results of the measured wavelength corrected by the calculated temperatures based on the thermistor resistances. As can be read from this graph, the lasing wavelength variations are of the order of ±0.005 nm, which sufficiently allows evaluations below the required long-term wavelength reliability of ±0.1 nm. Therefore, the correction of the measurements of the wavelengths by using the thermistor resistances provides adequate wavelength measurement accuracy.

In this connection, it is known that the wavelength variations described above are ascribable to fluctuations (0.009 nm/mA or so) resulting from the laser driving current Iₒₚ output from the laser driver (driving section) used in this test. The errors due to the fluctuations of this laser driving current I_{OP} are shown as error bars in FIG. 3.

It is also known that thermistors, upon high-temperature degradation-accelerating tests, cause an initial fluctuation phenomenon called “quenching” to increase in the resistance thereof. In the thermistor chip 15 of the present embodiment, the ACC energization at a temperature of 100° C. produces a resistance increase of 1%/1000-hour. Therefore, in addition to the calculated test temperature from the temperature calculating section 20, the increase in the thermistor resistance due to the quenching can be taken into account to correct the measured wavelength so that more accurate correction can be achieved for yet improved evaluation of the long-term wavelength reliability.

The present invention is described heretofore in conjunction with the preferred embodiment thereof. The measuring apparatus and method for the semiconductor laser device according to the present invention are, however, not limited to the configuration of the embodiment described above. The measuring apparatuses and methods obtained through various changes and modifications to the configuration of the embodiment described above also falls within the scope of the present invention.

As has been described, according to the measuring apparatus and method of the present invention, it is possible to monitor the lasing wavelength for a long term without wavelength variation due to changes in test temperature, thereby allowing high-accuracy evaluations of the long-term wavelength reliability while using a commercially-available inexpensive constant temperature bath.

What is claimed is:

1. An apparatus for evaluating a wavelength stability of a semiconductor laser device comprising a container for receiving therein a semiconductor laser device under test, a driving section for driving the semiconductor laser device, a wavelength measurement member for measuring an absolute wavelength of the semiconductor laser device during the driving, a temperature measurement member for measuring a test temperature of said semiconductor laser device, and a correction member for correcting the absolute wavelength measured by said wavelength measurement member based on said test temperature.

2. The apparatus as defined in claim 1, wherein said temperature measurement member includes a temperature sensor disposed in a vicinity of said semiconductor laser device, and a temperature calculating section for calculating said test temperature based on a signal detected by said temperature sensor.

3. The apparatus as defined in claim 2, wherein said temperature sensor is a thermistor.

4. The apparatus as defined in claim 3, wherein said correction member additionally corrects said test temperature measured by said temperature calculating section based on a quenching phenomenon of said thermistor.

5. The apparatus as defined in claim 1, wherein said container is a constant temperature bath.

6. A method for evaluating a wavelength stability of a semiconductor laser device comprising the steps of driving a semiconductor laser device under test received in a constant temperature bath, measuring an absolute wavelength of the driven semiconductor laser device, measuring a test temperature of said semiconductor laser device by using a temperature sensor disposed in a vicinity of said semiconductor laser device, and correcting the absolute wavelength measured by said wavelength measurement member based on said test temperature.

7. The method as defined in claim 6, wherein said temperature sensor is a thermistor.

8. The method as defined in claim 7, further comprising the step of correcting said test temperature based on a quenching phenomenon of said thermistor.
